(19) United States
(12) Patent Application Publication
(10) Pub. No.: US 2026/0113854 A1
(43) Pub. Date: Apr. 23, 2026

(54) AIR OUTLET BLADE

(71) Applicant: Chongqing Hudson New Energy Co., Ltd., Chongqing (CN)

(72) Inventors: Yujing Jiang, Chongqing (CN); Hui Yang, Chongqing (CN); Sheng Li, Chongqing (CN)

(21) Appl. No.: 19/361,812

(22) Filed: Oct. 17, 2025

(30) Foreign Application Priority Data
Oct. 17, 2024 (CN) 202422520906.8

(51) Int. Cl. H05K 5/02

(52) U.S. Cl. CPC H05K 5/0214

(57) ABSTRACT

The utility model provides an air outlet blade, including a flow guide plate and a baffle. The flow guide plate is horizontally arranged in the air outlet of the power generation box with its outer end bent downward. The flow guide plate is arranged obliquely. The baffle is horizontally arranged in the air outlet with its lower end connected to the end of the flow guide plate that is close to the inner cavity. The channel formed between two adjacent flow guide plates is used for the flow of heat-carrying gas, and the baffle is located in this channel above the flow guide plate. The presence of the baffle of the lower air outlet blade can block external dust and splashing raindrops. Compared with existing blades, it is more effective in blocking dust and raindrops.

### TECHNICAL FIELD

The utility model relates to the technical field of power generation equipment, in particular to an air outlet blade.

### BACKGROUND

The generating box is arranged outside the generating set, and the generating box can play a role in dust prevention and rain prevention. An air outlet is formed in the power generation box, and the air cooling and radiating device drives air flow to radiate the power generation unit and then is discharged from the air outlet.

In order to prevent excessive dust or raindrops from entering the power generation box from the air outlet, a plurality of blades is arranged at the air outlet along the vertical direction, and each blade is obliquely arranged, and the structure of the blade is similar to a shutter.

However, in the prior art, although the blades are disposed in an inclined arrangement, the dust-proof and rain-proof effects thereof are still poor, and the blades do not have a noise-reducing function.

### Disclosure of Utility Model

In view of the deficiencies of the prior art, the present utility model provides an air outlet blade that solves or at least alleviates one or more of the above-mentioned and other problems of the prior art.

The utility model provides an air outlet blade, comprising:
A flow guide plate, transversely arranged in the air outlet of the power generation box, with the end of the flow guide plate far away from the inner cavity of the power generation box bent downwards. The flow guide plate is arranged obliquely; and
A baffle, transversely arranged in the air outlet of the power generation box, and the lower end of the baffle is connected with one end of the baffle that is close to the inner cavity of the power generation box.

The baffle is located above the flow guide plate.

Preferably, one surface of the baffle, which faces away from the inner cavity of the power generation box, is in transition with the flow guide plate through a first cambered surface.

Preferably, the method further comprises:
A flow guide block that is connected with one end of the flow guide plate that is close to the inner cavity of the power generation box and is positioned above the flow guide plate. An open installation cavity is formed between the flow guide block and the baffle plate; and
A sound absorbing rod, arranged in the installation cavity.

Preferably, the upper end face of the flow guide block is in line with the upper end of the baffle plate.

Preferably, the surface of the baffle facing the flow guide block is in transition between the upper end surface of the flow guide plate through a second curved surface, and the second cambered surface is attached to the outer wall of the sound absorbing rod.

Preferably, the method further comprises:
A first bar-shaped limiting block connected with one surface of the upper end of the baffle towards the flow guide block.
A second bar-shaped limiting block connected with the surface of the upper end of the guide block that faces the baffle.

The first limiting block and the second limiting block can limit the position of the sound-absorbing rod. A columnar cavity along the length direction of the second cambered surface is formed in the second cambered surface, and the columnar cavity is connected to the installation cavity.

Preferably, the flow guide block is provided with a silencer cavity, and the upper end of the flow guide block is also provided with a silencer channel connected with the silencer cavity.

Preferably, a weight reducing groove is formed on the end of the flow guide block that is away from the baffle.

Compared with the prior art, the utility model has the following beneficial effects:

In this utility model, the cambered design at the end of the flow guide plate, combined with the baffle arrangement, achieves improved dust prevention and rain splash protection.

### DRAWINGS

In order to more clearly illustrate the embodiments of the present utility model or the technical solutions in the prior art, the drawings used in the description of the embodiments or the prior art will be briefly described below. Similar elements or portions are generally identified by similar reference numerals throughout the several figures. In the drawings, elements or portions thereof are not necessarily drawn to scale.

FIG. 1 is a side view of an air outlet blade according to an embodiment of the presented utility model;

FIG. 2 is a perspective view of the air outlet blade of FIG. 1;

FIG. 3 is a perspective view of one of the air outlet blades of FIG. 2.

### REFERENCE NUMERALS

10 flow guide plate;
20 baffle; 21 first cambered surface; 22 second cambered surface;
30 guide block; 31 installation cavity; 32 columnar cavity; 33 silencer cavity; 34 silencer channel; 35 weight reducing groove;
40 sound absorbing rod;
50 first bar-shaped limiting block; 51 second bar-shaped limiting block

### DETAILED DESCRIPTION

Embodiments of the technical scheme of the present utility model will be described in detail below with reference to the accompanying drawings. The following examples are only for more clearly illustrating the technical aspects of the utility model, and thus are merely examples, and are not intended to limit the scope of the presented utility model.

It is noted that unless otherwise indicated, technical or scientific terms used herein should be given the ordinary meaning as understood by one of ordinary skill in the art to which this utility model belongs.

In the description of the utility model, it should be understood that the terms “center”, “longitudinal”, “lateral”, “length”, “width”, “thickness”, “upper”, “lower”, “front”, “rear”, “left”, “right”, “vertical”, “horizontal”, “top”, “bottom”, “inner”, “outer”, “clockwise”, “counterclockwise”, “axial”, “radial”, “circumferential”, etc. indicate orientations or positional relationships based on the orientations or positional relationships shown in the drawings, and are merely for convenience in describing the present utility model and simplifying the description, and do not indicate or imply that the device or element being referred to must have a specific orientation, be configured and operated in a specific orientation, and therefore should not be construed as limiting the present utility model.

Furthermore, the terms “first,” “second,” and the like, are used for descriptive purposes only and are not to be construed as indicating or implying a relative importance or implicitly indicating the number of technical features indicated. In the description of the present utility model, the meaning of “plurality” is two or more unless specifically defined otherwise.

In the present utility model, unless explicitly specified and limited otherwise, the terms “mounted,” “connected,” “secured,” and the like are to be construed broadly, and may be, for example, fixedly connected, detachably connected, or integrally formed, mechanically connected, electrically connected, directly connected, indirectly connected via an intervening medium, or in communication between two elements or in an interaction relationship between two elements. The specific meaning of the above terms in the present utility model can be understood by those of ordinary skill in the art according to the specific circumstances.

In the present application, unless expressly stated or limited otherwise, a first feature positionally oriented “up” or “down” on a second feature may be the first and second features in direct contact, or the first and second features in indirect contact via an intervening medium. Moreover, a first feature being positionally oriented “above,” “over” and “on” a second feature may be a first feature being directly above or obliquely above the second feature, or simply indicating that the first feature is level higher than the second feature. The first feature being positionally oriented “under”, “below” and “beneath” the second feature may be the first feature being directly under or obliquely below the second feature, or simply indicating that the first feature is less level than the second feature.

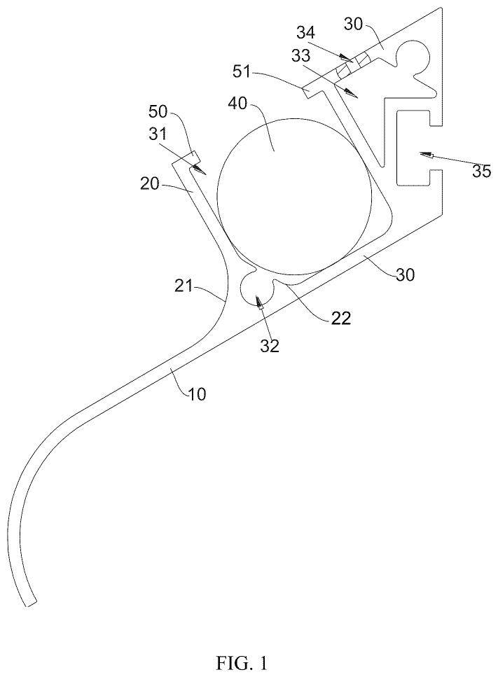

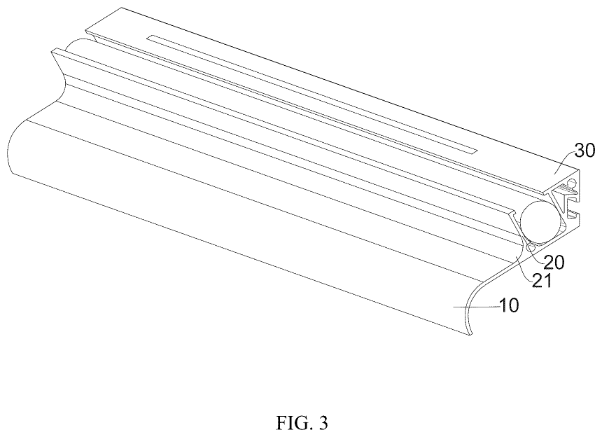

Referring to FIGS. 1 to 3, the present embodiment provides an air outlet blade including a flow guide plate 10 and a baffle plate 20.

The flow guide plate 10 is transversely arranged in an air outlet of the power generation box (not shown), and one end of the flow guide plate 10 away from the inner cavity of the power generation box is bent downwards. The flow guide plate 10 is arranged obliquely. Specifically, the two ends of the flow guide plate 10 along the length direction are respectively connected with the inner walls of the two sides of the air outlet. The baffle 20 is transversely arranged in an air outlet of the power generation box, and the lower end of the baffle 20 is connected with the end of the flow guide plate 10 that is close to the inner cavity of the power generation box. The baffle 20 is located above the flow guide plate 10. The channel formed between two adjacent flow guide plates 10 is for the flow of heat carrying gas, and a baffle 20 is located in the channel.

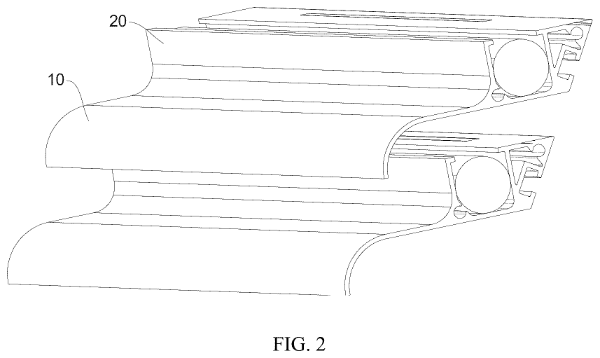

In this embodiment, referring to FIG. 2, the channel formed between the two air outlet blades is easy to enter raindrops or dust, one end of the above flow guide plate 10 of the air outlet blade is bent, and the existence of the baffle 20 of the below air outlet blade is matched to block the outside dust, splashed raindrops and other contaminants. As such, compared with the existing blade, the effect of preventing dust and splashed raindrops is better.

In one embodiment, the transition between baffle 20 and the flow guide plate 10 is provided by a first cambered surface 21.

In this embodiment, in addition to the dustproof effect, the ventilation of the air in the channels between the blades needs to be considered, so as to facilitate heat dissipation. When the hot air is discharged outwards through the channels among the blades, the hot air passes through the bent ends of the flow guide plates 10 and then downwards collides with the upper end surfaces of the adjacent flow guide plates 10. In addition, the arrangement of the first cambered surfaces 21 can enable part of the hot air to move along the upper end surfaces of the adjacent flow guide plates 10 under the flow guide of the first cambered surfaces 21, so that the whole hot air is smoothly discharged from between the two adjacent blades.

In one embodiment, the air outlet blade further includes a guide block 30 and a sound absorbing rod 40.

The guide block 30 is connected with one end of the flow guide plate 10, which is close to the inner cavity of the power generation box, the guide block 30 is positioned above the flow guide plate 10, and an open installation cavity 31 is formed between the guide block 30 and the baffle 20. The sound absorbing rod 40 is disposed in the installation cavity 31. Specifically, the guide block 30 is in a strip shape, and the guide block 30 is the same as the flow guide plate 10 and the baffle 20 in length. The sound-absorbing rod 40 employs a flame-retardant polyester sound-absorbing material having excellent weather resistance and water resistance. The generator set generates noise to induce vibration of the blades, and the vibration of the blades is reduced by the arrangement of the sound absorbing rod 40, thereby reducing noise.

In one embodiment, the upper end surface of the guide block 30 is in line with the upper end of the baffle 20.

In this embodiment, the hot air passes through the upper end of the guide block 30 and the upper end of the baffle 20 in order and moves along the cambered end of the flow guide plate 10 when being discharged from between the two blades. The upper end of the flow guide block 30 is in line with the upper end of the baffle 20, so that hot air can smoothly move from the upper end of the flow guide block 30 to the upper end of the baffle 20. Accordingly, the obstruction of the baffle 20 to the hot air is reduced.

In one embodiment, the surface of the baffle 20 facing the guide block 30 is transited with the upper end surface of the flow guide plate 10 by providing a second cambered surface 22, and the second cambered surface 22 is attached to the outer wall of the sound absorbing rod 40.

In this embodiment, the baffle 20 and the guide block 30 clamp the sound-absorbing rod 40 from two sides, and the second cambered surface 22 is mutually attached to the sound-absorbing rod 40. As such, the contact area between the sound-absorbing rod 40 and the installation cavity 31 is increased. Accordingly, the effect of eliminating the vibration of the blade by the sound-absorbing rod 40 is better, and the sound-absorbing rod 40 is more stable in the installation cavity 31.

In one embodiment, the air outlet blade further includes a first bar-shaped limiting block 50 and a second bar-shaped limiting block 51.

The first bar-shaped limiting block 50 is connected with the surface of the upper end of the baffle 20 that faces the flow guide block 30. The second bar-shaped limiting block 51 is connected to the surface of the upper end of the flow guide block 30 that is facing the baffle. The first stopper and the second stopper can limit the sound absorbing rod 40. The second cambered surface 22 is provided with a columnar cavity 32 along the length direction, and the columnar cavity 32 is connected to the installation cavity 31.

In this embodiment, since the baffle 20 has a certain elasticity, when the sound-absorbing rod 40 is installed and replaced, the baffle 20 can be easily bent due to the existence of the columnar cavity 32. Further, the sound-absorbing rod 40 is placed in the installation cavity 31 and is limited by the first bar-shaped limiting block 50 and the second bar-shaped limiting block 51.

In one embodiment, the flow guide block 30 is provided with a silencer cavity 33, and the upper end of the flow guide block 30 is also provided with a silencer channel 34 connected with the silencer cavity 33. The silencer channel 34 and the silencer cavity 33 constitute a Helmholtz resonator that can cancel noise passing between the two blades to some extent. In addition, one or more silencer cavities 33 may be provided, and silencer channels 34 may be correspondingly provided.

In one embodiment, the end of the flow guide block 30 facing away from the baffle 20 is provided with a weight reducing groove 35. The weight reducing groove 35 can reduce the weight of the whole air outlet blade.

In the description of the present utility model, numerous specific details are set forth. However, it is understood that embodiments of the utility model may be practiced without these specific details. In some instances, well-known methods, structures and techniques have not been shown in detail in order not to obscure an understanding of this description.

It should be noted that the above embodiments are only used to illustrate the technical solution of the present utility model, but not to limit the technical solution of the present utility model. Furthermore, although the detailed description of the present utility model is given with reference to the above embodiments, it should be understood by those skilled in the art that the technical solution described in the above embodiments may be modified or some or all technical features may be equivalently replaced, and these modifications or substitutions do not make the essence of the corresponding technical solution deviate from the scope of the technical solution of the embodiments of the present utility model. Further, all the modifications or substitutions are included in the scope of the claims and the specification of the present utility model.

1. An air outlet blade, comprising:
a flow guide plate that is transversely arranged in an exhaust port of a power generation box, wherein one end of the flow guide plate is orientally positioned away from an inner cavity of the power generation box being bent downward, and wherein the flow guide plate is arranged obliquely;
a baffle that is transversely arranged in the exhaust port of the power generation box, and its lower end is connected to an end of the flow guide plate close to the inner cavity of the power generation box; and
wherein the baffle is located above the flow guide plate.

2. The air outlet blade according to claim 1, wherein a first cambered surface is disposed between a side of the baffle facing away from the inner cavity of the generator box and the flow guide plate.

3. The air outlet blade according to claim 1, further comprising a guide block connected to one end of the flow guide plate close to the inner cavity of the generator box, wherein the guide block is located above the flow guide plate, and wherein an open installation cavity between the guide block and the baffle is formed; and
a sound absorbing rod that is arranged in the installation cavity.

4. The air outlet blade according to claim 3, wherein the upper end surface of the guide block is in line with the upper end of the baffle.

5. The air outlet blade according to claim 3, wherein a side of the baffle facing the guide block transitions to the upper end surface of the flow guide plate as a second cambered surface;
wherein the second cambered surface is in contact with the outer wall of the sound-absorbing rod.

6. The air outlet blade according to claim 5, further comprising:
a first bar-shaped limiting block is connected to a side of the upper end of the baffle facing the guide block;
a second bar-shaped limiting block is connected to a side of the upper end of the guide block facing the baffle;
wherein the first bar-shaped limiting block and the second bar-shaped limiting block can limit the sound-absorbing rod;
wherein a columnar cavity is disposed on the second cambered surface along its length direction; and
wherein the columnar cavity links to the installation cavity.

7. The air outlet blade according to claim 6, wherein a silencer cavity is disposed on the guide block; and
wherein a silencer channel connecting to the silencer cavity is further disposed at the upper end of the guide block.

8. The air outlet blade according to claim 7, wherein a weight-reducing groove is disposed on one end of the guide block facing away from the baffle.
